(19) United States
(12) Patent Application Publication
(10) Pub. No.: US 2017/0184863 A1
(43) Pub. Date: Jun. 29, 2017

(54) COOLING SYSTEM FOR HEAD MOUNTED DEVICE

(71) Applicant: SULON TECHNOLOGIES INC., Markham (CA)

(72) Inventors: Dhanushan BALACHANDRESWARAN, Richmond Hill (CA); Weizhong HU, Mississauga (CA); Kibaya Mungai NJENGA, Markham (CA); Adam Nicholas SEANGIO, Toronto (CA)

(21) Appl. No.: 15/389,570

(22) Filed: Dec. 23, 2016

Related U.S. Application Data
(60) Provisional application No. 62/387,482, filed on Dec. 24, 2015.

(51) Int. Cl. G02B 27/01; H05K 7/20

(52) U.S. Cl. CPC G02B 27/0176; G02B 27/0172; H05K 7/20172; H05K 7/20409; H05K 7/20145; G02B 2027/0161; G02B 2027/0138

(57) ABSTRACT

A cooling system is provided for a head mounted device for augmented reality applications. The head mounted device has a visor housing having one or more exhaust vents and one or more intake vents, a motherboard disposed within the visor housing, at least one processor mounted to the motherboard and at least one camera mounted to the motherboard. At least a pair of cooling subsystems disposed within the visor housing provide generally balanced horizontal weight to the visor housing. The cooling subsystems are arranged to receive air flow through the intake vents and transfer heat generated by the at least one processor to air exhausted from the exhaust vents.

### TECHNICAL FIELD

The following relates generally to cooling of electronic circuitry and more particularly to cooling of a head mounted device having electronic circuitry therein.

### BACKGROUND

Augmented reality (AR) and virtual reality (VR) visualisation applications are increasingly popular. The range of applications for AR and VR visualisation has increased with the advent of wearable technologies and 3-dimensional (3D) rendering techniques. AR and VR exist on a continuum of mixed reality visualisation.

Various wearable devices for AR and VR applications are implemented as head mounted devices (HMDs). Various existing HMDs do not have an excessive heat generation problem because they are implemented with relatively weak processors. This is commonly the case for HMDs which are conduits for viewing a smartphone display and utilizing built-in smartphone processors for generation of AR and VR environments and objects.

Conversely, increasing processing capabilities onboard various HMDs may correspond to elevated heat generation by onboard systems. Device performance, as well as user comfort or safety may suffer from elevated device temperatures.

### SUMMARY

In one aspect, a head mounted device for augmented reality applications is provided, the head mounted device comprising at least one cooling subsystem comprising a fan.

In another aspect, a head mounted device for augmented reality applications is provided, the head mounted device comprising: a visor housing having two or more exhaust vents and one or more intake vents; a motherboard disposed within the visor housing; at least one processor mounted to the motherboard; at least one camera mounted to the visor housing; and at least a pair of cooling subsystems disposed within the visor housing to dissipate heat generated by the at least one processor from the exhaust vents and receive air flow from the intake vents, the cooling subsystems arranged to provide generally balanced horizontal weight to the visor housing.

In yet another aspect, a cooling system is provided for an augmented or virtual reality (AR/VR) head mounted device (HMD). The HMD comprises a visor housing having a display viewable by a user wearing the HMD and electronics for driving the display. The cooling system is disposed predominantly on an opposing side of the display from the user so as to not obstruct viewing of the display by the user. The cooling system comprises: a plurality of fans directing airflow outward from the HMD to an environment surrounding the HMD, and at least two of the plurality of fans are disposed along opposing sides of a vertical midpoint of the HMD.

In a further aspect, an AR or VR HMD is provided. The HMD comprises: a visor housing having a display viewable by a user wearing the HMD electronics for driving the display, and a cooling system disposed predominantly on an opposing side of the display from the user so as to not obstruct viewing of the display by the user. The cooling system comprises: a plurality of fans directing airflow outward from the HMD to an environment surrounding the HMD. At least two of the plurality of fans being disposed along opposing sides of a vertical midpoint of the HMD.

In a still further aspect, a cooling system is provided for an AR or VR HMD. The HMD comprises a visor housing having a display viewable by a user wearing the HMD and electronics for driving the display. The cooling system is disposed predominantly on an opposing side of the display from the user so as to not obstruct viewing of the display by the user, and the cooling system comprises at least one fan directing airflow upward from the HMD.

These and other aspects are contemplated and described herein. It will be appreciated that the foregoing summary sets out representative aspects of systems and methods, to assist skilled readers in understanding the following detailed description.

### DESCRIPTION OF THE DRAWINGS

A greater understanding of the embodiments will be had with reference to the Figures, in which:

FIG. 1 is a top perspective view of an HMD for AR applications;

FIG. 2 is a front view of a motherboard for an HMD illustrating a first embodiment of a cooling system with fans mounted parallel to the motherboard;

FIG. 3 is a bottom perspective view of the motherboard;

FIG. 4 is a rear view of components that are mounted to the motherboard;

FIG. 5 is a rear view of the motherboard;

FIG. 6 is a side cross-sectional view of the motherboard and a display of the HMD taken along the line 6-6 in FIG. 4;

FIG. 7 is a side view of the HMD;

FIG. 8 is a bottom perspective view of the HMD;

FIG. 9 is an air flow diagram showing an embodiment of the cooling system in use;

FIG. 10 is a top perspective view of a second embodiment of the cooling system and motherboard with the fans of the cooling system disposed transversely to the motherboard;

FIG. 11 is an exploded perspective view of the second embodiment illustrating a vent configuration of the visor housing;

FIG. 12 is an isolated view of heat pipes and a heat sink of the second embodiment;

FIG. 13 is an exemplary HMD configured for use with the second embodiment;

FIG. 14 is a heat map from an exemplary thermal simulation conducted using the second embodiment;

FIG. 15 is a front perspective view of a third embodiment of the cooling system with fans mounted parallel to the motherboard and along an outer surface of the motherboard;

FIG. 16A is a front perspective view of an exemplary HMD with a top panel shown removed, configured for use with of a fourth embodiment of the cooling system with in which fans are mounted transversely to the motherboard and having fan inlets are directed to the environment;

FIG. 16B is a front perspective view of the exemplary HMD of FIG. 16A with the top panel shown in place;

FIG. 17 illustrates an embodiment of the cooling system incorporating a rounded heat pipe having a plurality of transverse heat fins disposed around a radial fan;

FIG. 18 illustrates a panel of the HMD's visor housing having perforations disposed therethrough;

FIG. 19A is a front perspective view in schematic form of a configuration of the motherboard and cooling system for an HMD;

FIG. 19B is a front perspective view in schematic form of another configuration of the motherboard and cooling system for an HMD;

FIG. 19C is a front perspective view in schematic form of still another configuration of the motherboard and cooling system for an HMD; and

FIG. 20 is a front view of another embodiment of the cooling system with a single fan disposed parallel to the motherboard.

### DETAILED DESCRIPTION

For simplicity and clarity of illustration, where considered appropriate, reference numerals may be repeated among the Figures to indicate corresponding or analogous elements. In addition, numerous specific details are set forth in order to provide a thorough understanding of the embodiments described herein. However, it will be understood by those of ordinary skill in the art that the embodiments described herein may be practised without these specific details. In other instances, well-known methods, procedures and components have not been described in detail so as not to obscure the embodiments described herein. Also, the description is not to be considered as limiting the scope of the embodiments described herein.

Various terms used throughout the present description may be read and understood as follows, unless the context indicates otherwise: “or” as used throughout is inclusive, as though written “and/or”; singular articles and pronouns as used throughout include their plural forms, and vice versa; similarly, gendered pronouns include their counterpart pronouns so that pronouns should not be understood as limiting anything described herein to use, implementation, performance, etc. by a single gender; “exemplary” should be understood as “illustrative” or “exemplifying” and not necessarily as “preferred” over other embodiments. Further definitions for terms may be set out herein; these may apply to prior and subsequent instances of those terms, as will be understood from a reading of the present description.

Any module, unit, component, server, computer, terminal, engine or device exemplified herein that executes instructions may include or otherwise have access to computer readable media such as storage media, computer storage media, data libraries, or data storage devices (removable and/or non-removable) such as, for example, magnetic discs, optical discs, or tape. Computer storage media may include volatile and non-volatile, removable and non-removable media implemented in any method or technology for storage of information, such as computer readable instructions, data structures, program modules, or other data. Examples of computer storage media include RAM, ROM, EEPROM, flash memory or other memory technology, CD-ROM, digital versatile discs (DVD) or other optical storage, magnetic cassettes, magnetic tape, magnetic disc storage or other magnetic storage devices, or any other medium which can be used to store the desired information and which can be accessed by an application, module, or both. Any such computer storage media may be part of the device or accessible or connectable thereto. Further, unless the context clearly indicates otherwise, any processor or controller set out herein may be implemented as a singular processor or as a plurality of processors. The plurality of processors may be arrayed or distributed, and any processing function referred to herein may be carried out by one or by a plurality of processors, even though a single processor may be exemplified. Any method, application or module herein described may be implemented using computer readable/executable instructions that may be stored or otherwise held by such computer readable media and executed by the one or more processors.

The following relates to a cooling system for a head mounted device (HMD). In the disclosed system, an HMD suitable for AR applications is provided in which the HMD comprises a cooling system configured to transfer heat from the HMD to the environment. The cooling system comprises one or more exhaust vents, one or more intake vents, one or more heat pipes, one or more fans and one or more heat sinks.

The term “AR” as used herein may encompass several meanings. In the present disclosure, AR includes: visualization or interaction by a user with real physical objects and structures along with virtual objects and structures overlaid thereon; and viewing or interaction by a user with a fully virtual set of objects and structures that are generated to include renderings of physical objects and structures and that may comply with scaled versions of physical environments to which virtual objects and structures are applied, which may alternatively be referred to as an “enhanced virtual reality”. Further, the virtual objects and structures could be dispensed with altogether, and the AR system may display to the user a version of the physical environment which solely comprises an image stream of the physical environment. Finally, a skilled reader will also appreciate that by discarding aspects of the physical environment, the systems and methods presented herein are also applicable to virtual reality (VR) applications, which may be understood as “pure” VR. For the reader's convenience, the following may refer to “AR” but is understood to include all of the foregoing and other variations recognized by the skilled reader.

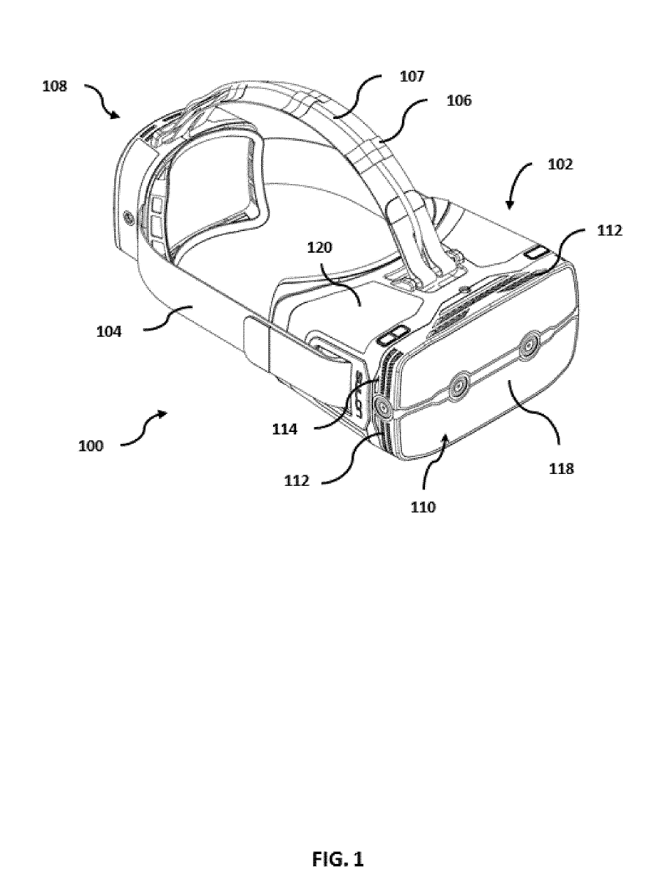

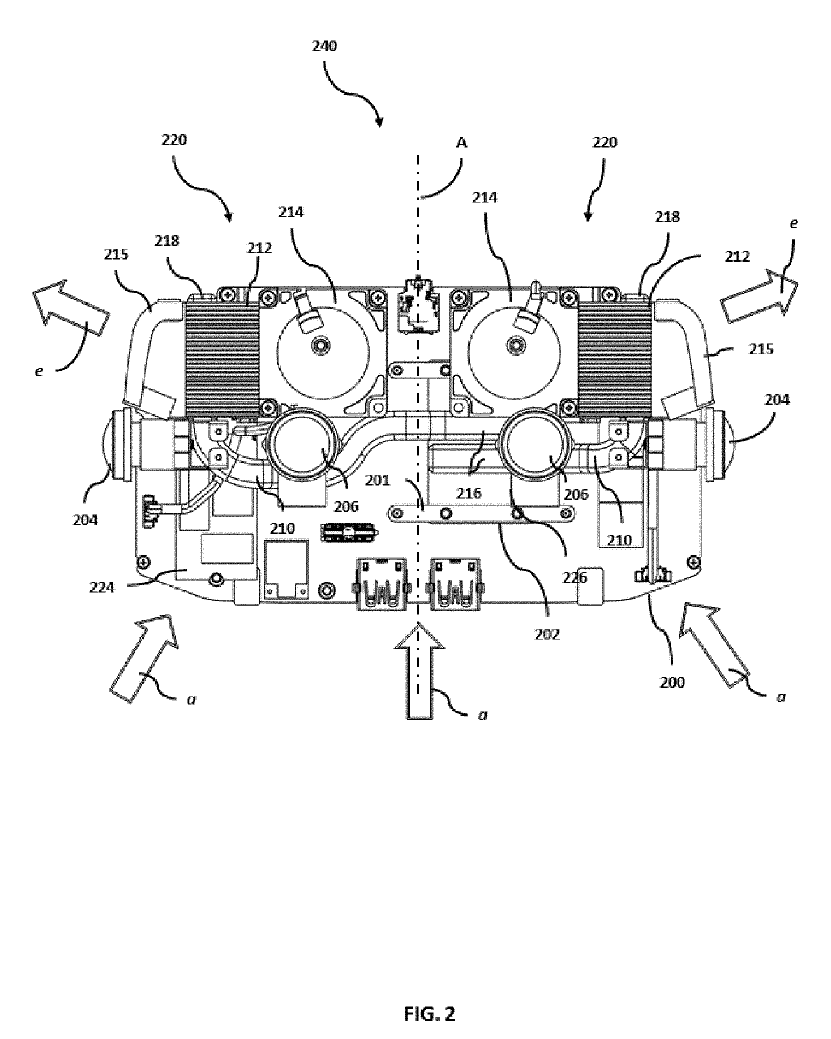

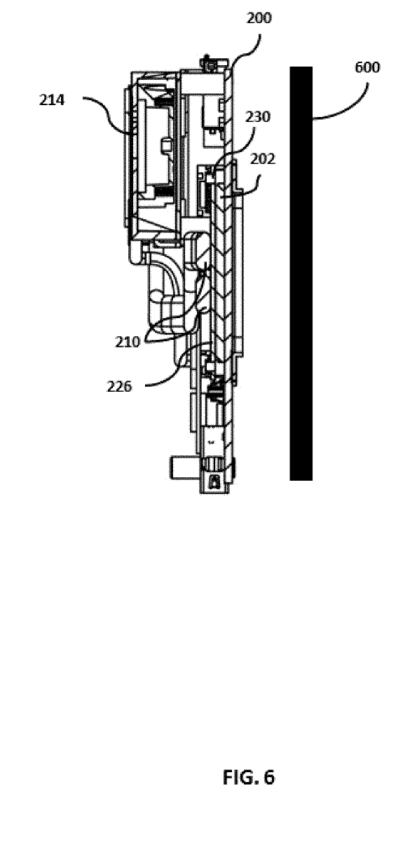

Referring first to FIG. 1, an exemplary HMD 100 is shown. The HMD 100 is a particular arrangement suitable for AR and VR applications and comprises a visor housing 102 coupled to a headband 104 and a transverse head support 106. The HMD 100 shown further comprises a battery pack 108 that is electrically coupled to the systems in the visor housing 102 by an overhead power supply cable 107. The battery pack permits wireless operation, i.e., use of the HMD without tethering to any power sources that are fixed in the physical environment. The visor housing 102 generally houses a display 600 (shown in FIG. 6) and, in particular applications, further houses electronics (not shown in FIG. 1) that drive the display and generate AR gameplay and environments. The visor housing comprises a plurality of housing panels, such as front panel 118 and side panels 120. The display faces the user when worn, and typically the HMD 100 is placed in close abutting relationship to a user's face around the user's eyes. An HMD for AR applications generally comprises at least one camera to capture the real world environment. The HMD 100 shown in FIG. 1 has a camera system 110 with at least one camera, as described more fully in reference to FIG. 2.

The visor housing 102 houses various heat sources. To dissipate heat from those sources, the visor housing 102 comprises a plurality of exhaust vents 114 and intake vents 112 disposed around the periphery of the visor housing. The exhaust vents 114 are disposed on either side of the HMD along the top portion of each side. The intake vents 112 are disposed along the top, bottom and sides of the periphery and separated from adjacent exhaust vents by a closed region to prevent or reduce reintroduction of the exhaust air into the intake air. The exhaust vents and intake vents are embodied as louvered apertures (“louvres”). The louvres can be used to control the direction of airflow.

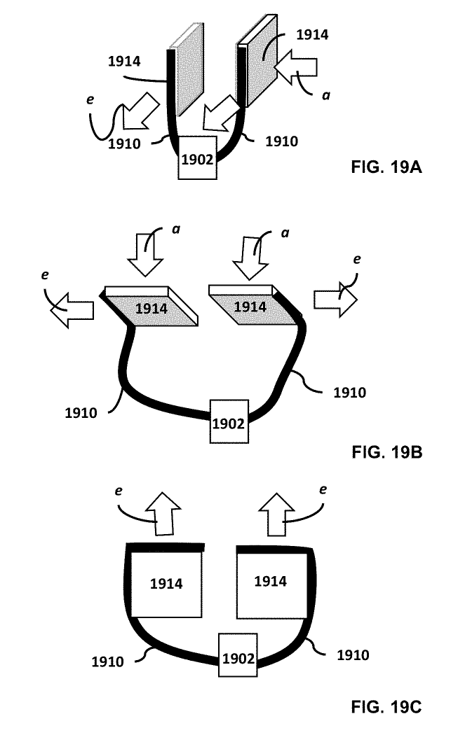

In addition to the exhaust vents described more fully herein, various surfaces of the HMD may by perforated to enhance airflow by admitting air into or out of the interior of the visor housing. For example, perforations may be provided by grills, louvres and, and perforations in surfaces of the HMD, such as the front panels 118 and side panels 120 shown in FIG. 1. Further to enhancing airflow, this also may provide weight reduction, since the perforations provide voids that are weightless. The perforations may be lined with thermally conductive materials that enhance heat transfer, which may be referred to as “thermal vias”, as described in more detail below with reference to FIGS. 19A to 19C. Further, the perforations may be metallized to enhance thermal conductivity from the surface of the visor housing.

Referring now to FIGS. 2, 3 and 5, a front view and corresponding perspective and rear views of an exemplary motherboard 200 and a first embodiment of the cooling system 250 for an HMD are shown. The motherboard 200 is secured within the visor housing, typically by a plurality of fasteners. The motherboard 200 is shown as a printed circuit board, which is generally considered a typical implementation; however, other forms of providing a processor and supporting electronics could also be used. Examples include a dedicated integrated circuit, flexible PCB, several interconnected boards, etc.

The motherboard 200 has electrically coupled and mounted thereto at least one central processor 202, which may be a CPU, GPU, APU, FPGA, or other processor. The processor 202 of the HMD 100 is configured to perform major computational tasks onboard the HMD 100. Examples of such functions would be understood upon a review of the art including applicant's prior patents and patent applications and may include, for example, mapping, position determination, movement, image generation, etc.

The processor 202 generates heat during operation, which may result in undesirable, uncomfortable, unsafe or inoperable conditions for the HMD and/or its user. For example, the temperature of the motherboard or the processor may exceed a threshold temperature leading to damage or destruction of the processor or other components of the HMD, or to a responsive depowering of the processor to reduce heat generation at the expense of system performance, or to user discomfort. As an example, it may be preferable to maintain a processor temperature under 100° C., particularly in normal operating conditions such as where the ambient air is at a temperature of approximately 25° C. It is also preferable to maintain a visor housing temperature under 45° C. for user comfort; however, higher localized temperatures may be tolerated.

In the illustrated embodiment, the motherboard 200 of FIG. 2 is further electrically coupled to the camera system 110, which has four cameras, including two side-facing cameras 204 disposed at lateral ends thereof and facing laterally outwardly therefrom, two front-facing cameras 206 disposed between the two side-facing cameras at an offset from the surface of the motherboard. It will be appreciated the present cooling system can operate similarly regardless of the camera configuration of the HMD. In this embodiment, all the cameras face toward the environment through apertures within the visor housing, as shown in FIG. 1. The two front-facing cameras 206 are disposed in substantially coaxial alignment to a typical user's line of sight in a resting position to capture a stereoscopic image stream that mimics the user's real view into the environment. The substantially coaxial alignment may facilitate translation of the AR environment to the user to appear seamless and “immersive”. The five cameras are preferably disposed in a plane that is normal to the motherboard and visor housing. The plane substantially bisects the motherboard and visor housing into upper and lower sections relative to a user's face when worn. The display, which is electrically coupled to the motherboard and generally adjacent the opposite face of the motherboard from the cameras and facing in the opposite direction of the cameras, is substantially centred relative to the motherboard and the visor housing so that the vertical centre of the display is substantially coincident with the user's line of sight in the resting position. In general, then, the positions of at least the left and right front-facing cameras 206 are considered important for providing stereoscopic capture in this embodiment of the HMD 100 and cannot be modified substantially without further modification to the HMD.

As will be appreciated from the exemplary motherboard 200 shown in FIG. 2, an HMD motherboard may be crowded with relatively large components for which the range of available positions is fixed or limited by the functional aspects of the HMD. Placement of the processor and other electronics, therefore, must be made in view of the cameras and any other components (not shown or described) that are considered position-sensitive.

It has been found preferable for an HMD to be substantially balanced between its left and right sides so that a user wearing the HMD does not perceive significant lopsided strain, which may lead to discomfort.

Furthermore, in computing-intensive applications, the amount of heat generated by the processor may not be handled sufficiently by a single set of cooling subsystems that can be completely disposed proximate the processor. In many examples, cooling subsystems are larger than the available motherboard space near the processor.

The presently described motherboard 200, therefore, comprises at least a pair of cooling subsystems 220 horizontally weight balanced upon the motherboard. In the figures, two such cooling subsystems 220 are shown in paired and substantially mirrored arrangement. The cooling subsystems 220 are preferably disposed along the upper region of the motherboard and HMD, as shown, and vented with louvres from upper portions of sides of the HMD. Since heat rises, it is preferable not to direct exhaust out of the bottom of the visor housing. It may also be preferable not to direct exhaust air upward from the top of HMD as such exhaust would be in the walking path of the user's forehead in many cases. Alternatively, it may be preferable to direct exhaust upward from the top of the HMD in order to benefit from the tendency of hot air to rise and further induce airflow through the cooling system.

In the example shown, the cooling subsystems 220 comprise a heat sink 226, a pair of heat pipes 210, fins 212 and radial fans 214. The mirrored arrangement of the cooling subsystems 220 may achieve a more balanced weight distribution of the cooling subsystems between the left and right sides of the HMD, while the pairing of the cooling subsystems 220 permits two fans to be incorporated instead of one, thereby reducing the distance required between the centre of the motherboard and the top edge of the visor housing to accommodate the fans, in contrast to a design incorporating a single fan having equivalent volumetric flow to the combined volumetric flow of the paired fans.

The heat sink 226 has a face in abutting relationship to a face of the processor 202. Thermal grease or paste which acts as a thermally conductive membrane is placed in the interface between the heat sink 226 and the processor 202 to ensure heat transfer across the respective abutting surfaces of the processor and the heat sink. Thermal grease which may be particularly suitable includes, for example, X23-7762 or X23-7783D. The heat sink may be mounted to the motherboard in a tight fit to the processor by the use of mounting brackets 201. The heat sink is preferably tight enough to force the heat sink into contact with the processor but not to crack the processor or motherboard.

Each of the heat pipes 210 comprises a heat sink end 216 and a dissipation end 218. The heat sink end 216 is thermally coupled to the heat sink 203 and the two heat pipes 210 extend generally horizontally therefrom toward opposite sides of the motherboard 200. The heat pipes 210 may be jogged to navigate around other components, such as is the case with the heat pipe 210 being jogged around the left front-facing camera 206. The heat pipes 210 are then bent upwardly prior to reaching the side-facing cameras 204 and the dissipation end 218 of each heat pipe 210 terminates at the upper edge of the motherboard 200. Depending upon available depth between the surface of the motherboard and obstacles disposed at an offset from the surface, the heat pipes 210 may be round or partially flattened (ovular). By flattening the heat pipes, their depth (i.e., the distance between the surface of motherboard and the other components) may be reduced, thereby permitting greater airflow across the surface of the motherboard than entirely round heat pipes. A flatter profile may further enhance airflow through the fins without reducing the exposed surface area of the heat pipes

The fins 212 are thermally coupled to the dissipation end of each heat pipe 210 to absorb heat therefrom, and the radial fans 214 are disposed adjacent to the fins at a position between the fins 212 and the central vertical axis A of the motherboard 200. As shown in FIGS. 19A and 19B, the fans may be disposed along the side or top of the visor housing (i.e., transverse of the surface of the motherboard), or, as shown in FIG. 19C, the fans may be adjacent the surface of the motherboard (i.e. approximately parallel the surface of the motherboard). In the embodiment of FIG. 2, the fans are adjacent the surface of the motherboard. The combination of the fins 212 and radial fans 214 is selected such that their combined footprints do not exceed the space available on the PCB between the upper edge of the motherboard 200, the front-facing cameras 206, the side-facing cameras 204 and the central vertical axis A of the motherboard 200. In operation, each fan 214 draws ambient air through the intake vents into the visor housing as shown by arrows a, and blows the air across the fins 212 and the dissipation end 218 of the heat pipe 210, through the outlet 215 and exhaust vents 214 into the surrounding environment as shown by the arrows e.

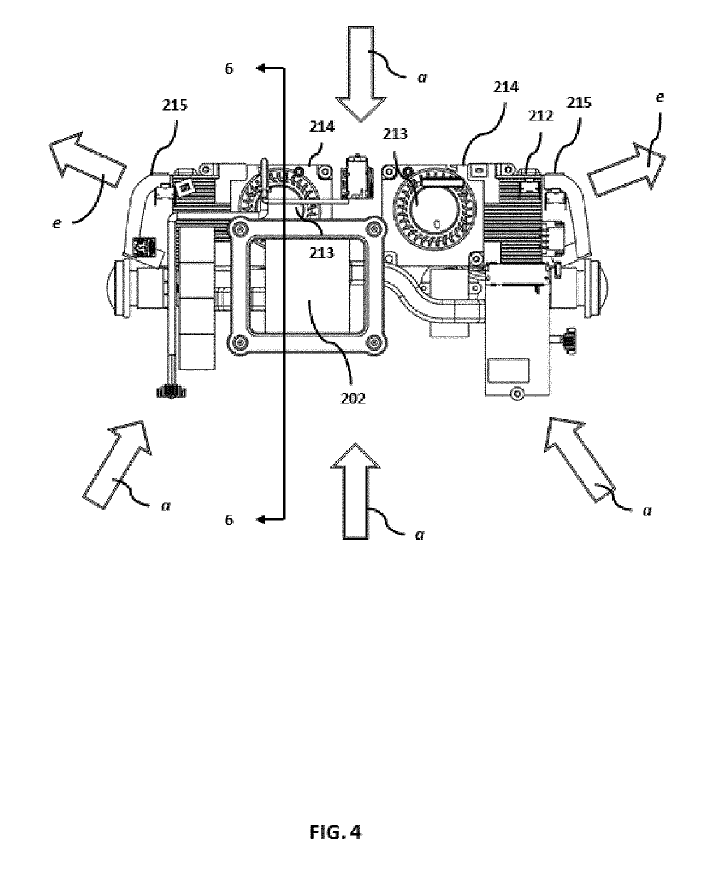

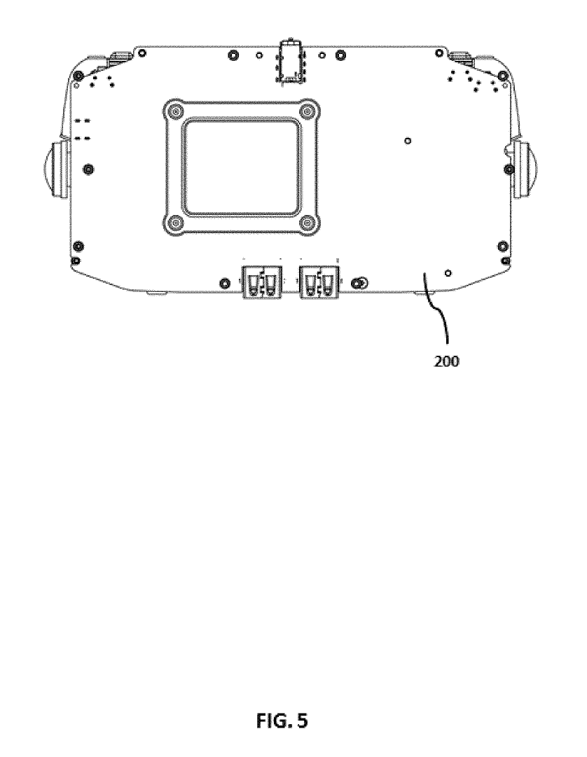

Referring now to FIG. 4, a rear view is shown wherein the components mounted to the motherboard are shown with the motherboard removed from view. For reference, this is a view as would be seen by a wearer of the HMD if at least the motherboard and display were absent from the user's view. With the motherboard present, the corresponding view is generally as in FIG. 5. A corresponding cross-sectional side view along line 6-6 of FIG. 4 is shown in FIG. 6, with the addition of a cross-sectional side view of the display 600.

The cooling subsystems may be mounted to the motherboard in a variety of ways. For example, each component of the cooling subsystems could be mounted individually to the motherboard. However, preferably the components of each cooling subsystem are fastened to one another to reduce the number of connection points to the motherboard. Further, the components of each cooling subsystem are preferably thermally or fluidly coupled to one another. In turn, the cooling subsystem may have a minimum sufficient number of connection points for mounting to the motherboard, which reduces transmission of vibration and other motion artifacts from the cooling subsystems to the motherboard, and mitigates weight gain to the HMD.

The mounting mechanism between the cooling subsystems and the motherboard is also preferably selected to reduce vibration. For example, the mounting mechanism may comprise silicone or other flexible gaskets. Further, the cooling subsystems are preferably mounted as closely to the motherboard as reasonably possible, since increased distance from the motherboard tends to amplify vibration induced by any moving cooling subsystems.

Preferably, the cooling subsystems are mounted to the motherboard only wherever there are no components obstructing the space between the elements and the motherboard, so that any fasteners for mounting the cooling subsystems to the motherboard avoid touching any components on the motherboard. Nevertheless, there may be a minimum required spacing between the cooling subsystems, or at least components thereof, and the motherboard. For example, it has been found that the heat pipes, whose surface temperatures may reach approximately 70°, are preferably spaced at least approximately 2 millimeters from the surface of any heat-sensitive components mounted to the motherboard to ensure sufficient thermal clearance.

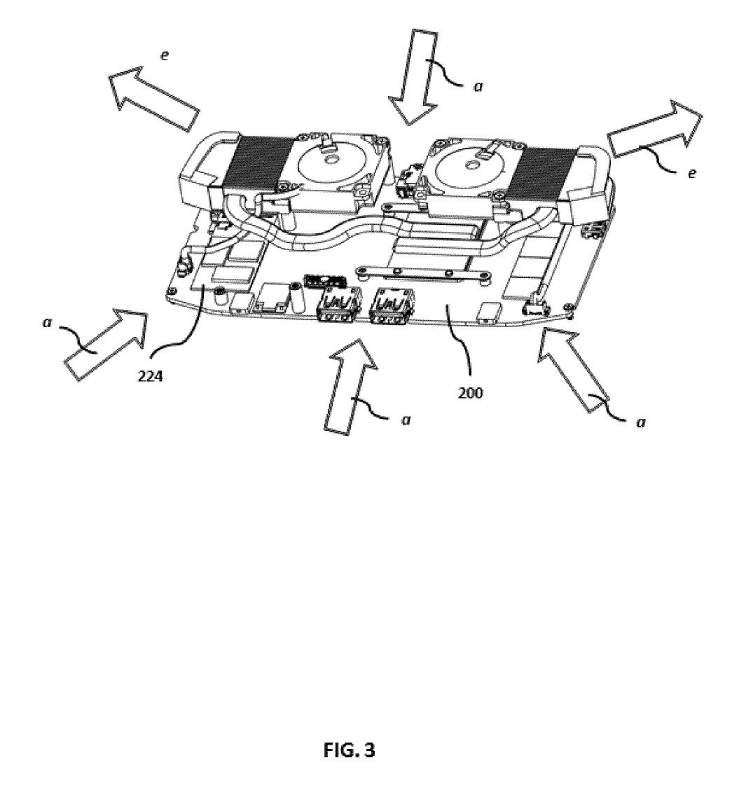

Still further, increased distance between a user's face and any moving elements of the cooling subsystems tends to amplify the vibrations sensed by the user. Therefore, it may be preferable when possible to reduce the distance between the moving elements and the user's face. Yet still further, the cooling subsystems preferably are spaced at a sufficient distance to enable access to any components mounted to the motherboard which are desired to be readily removed or replaced without needing to disassemble the motherboard. For example, an SSD card 224 shown in FIG. 3 may require sufficient clearance from the heat pipe to be lifted at least 10° away from the motherboard in order to be removed and/or replaced; therefore, the heat pipe may be jogged or offset to provide sufficient clearance for removal.

It is also preferable to include a gasketed conduit or outlet between the heat dissipation end of the heat pipes and the exhaust vents, to further mitigate vibration and heat transmission to the motherboard and visor housing. This outlet provides a further benefit of permitting the louvres to be formed in a specialized contour along the periphery of the HMD, which is typically for aesthetic purposes, while permitting the use of non-customized fans. As an example, this permits the HMD to have rounded corners even if the fans are not manufactured with rounded corners, as shown in FIGS. 1 and 2, where the gasketed outlet 215 runs from fins 212 to the exhaust vent 114. The gasket serves as the interface between the outlet 215 and the exhaust vent 114.

As shown in FIG. 4, each radial fan 214 is disposed with its fan inlet 213 facing toward the motherboard, and spaced at an offset therefrom to provide an air gap between the radial fan 214 and the motherboard through which the radial fan 214 may draw air from within the visor housing. In another embodiment, the inlet is in fluid communication with the portion of the HMD that is adjacent the user's face. For example, the HMD may have a gasket providing a relatively tight seal to the user's face. This is typical among AR HMDs to provide cushioning and to prevent ambient light from interfering with the user's view of the display. In these cases, there is an air cavity between the user's face and the display of the HMD. The fan inlet may be disposed adjacent a passage between the cavity and the forward region of the visor housing or in communication with the cavity by a conduit or channel through which air can pass. This may achieve a dual effect of venting the heat from the heat pipes and also extracting and venting air from the user's face, which may otherwise cause humidity embodied as fogging and/or sweating. An alternative or additional humidity mitigation technique is to provide air gaps in the gasket. Preferably, the air gaps are provided at least at the bottom and top of the gasket. Due to the stack effect, whereby the user's face generates heat causing warmer air to rise, inducing air flow, air is drawn from the cavity between the screen and the user and exhausted into the physical environment.

It is possible that the radial fans could have a corresponding inlet on the opposing surface of the fans, i.e., facing forward along the user's gaze when wearing the HMD; however, it may be preferable to at least have an inlet in the surface of the fan that faces the motherboard to draw hot air from the motherboard and the components mounted thereto. The use of radial, rather than axial, fans is preferred due to the generally shallower profile of radial fans relative to equivalent axial fans, thereby minimizing the depth of the cooling system within the visor housing. Exemplary radial fans have a throughput of >˜2 cfm with combined throughput from a pair of fans of >˜4 cfm. It is preferable that the fans emit a sound of at most 40 dB during system idle. A higher throughput can increase cooling, but this is a good compromise in terms of power consumption, cooling, noise, and space. The fans are preferably selected from low-noise types. Exemplary fans include brushless fan motors, which may be longer lasting than brushed fan motors. Exemplary fans are approximately 38 mm×38 mm radial fans.

Each radial fan 214 comprises an impeller (not visible) which draws air from the fan inlet 213 and drives it across the fins 212 of the heat pipe 210 and then along the respective fan outlet 215 to exit the visor housing through the exhaust vent into the environment surrounding the HMD, as shown by the arrows e. The exhaust vent preferably is configured to expel exhaust air away from the intake vents so that it is not immediately reintroduced into the visor housing after being exhausted into the physical environment. For example, the exhaust vent may comprise louvres that, in cooperation with the outlets 215, exhaust air from opposing sides of the visor housing.

The radial fans are preferably selectively controlled by the processor or another controller, such as, for example, an embedded controller or a micro controller. The visor housing may comprise a thermometer and other sensors to obtain and provide to the controller temperature and/or air flow readings relating to the ambient air (i.e., the intake air), exhaust air, the processor temperature, and temperature within the visor housing. The control may be by pulse-width modulation (PWM) to control fan speeds based upon the sensor readings and based upon a preconfigured acceptable processor temperature range. The controller preferably can partially or completely depower the processor in response to higher temperature readings, but at the expense of processing performance. Alternatively or additionally, the controller may have another mode in which components are allowed to exceed “normal” temperatures for high computing performance at the expense of user comfort. The controller may be configured to reduce fan speeds in response to detecting lower than threshold component temperatures, thereby reducing power consumption and noise from the cooling system.

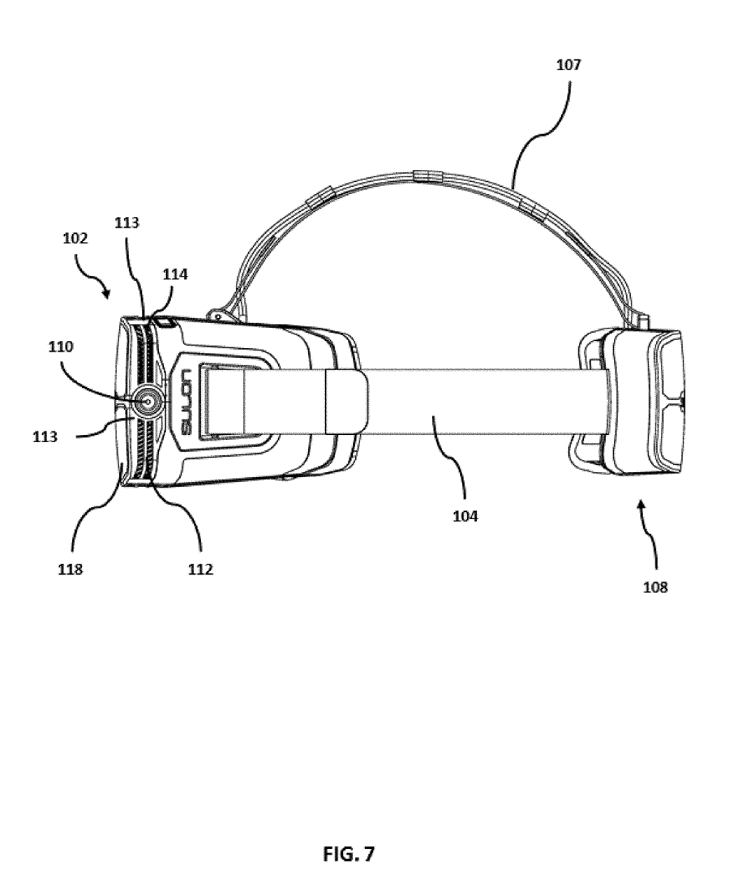

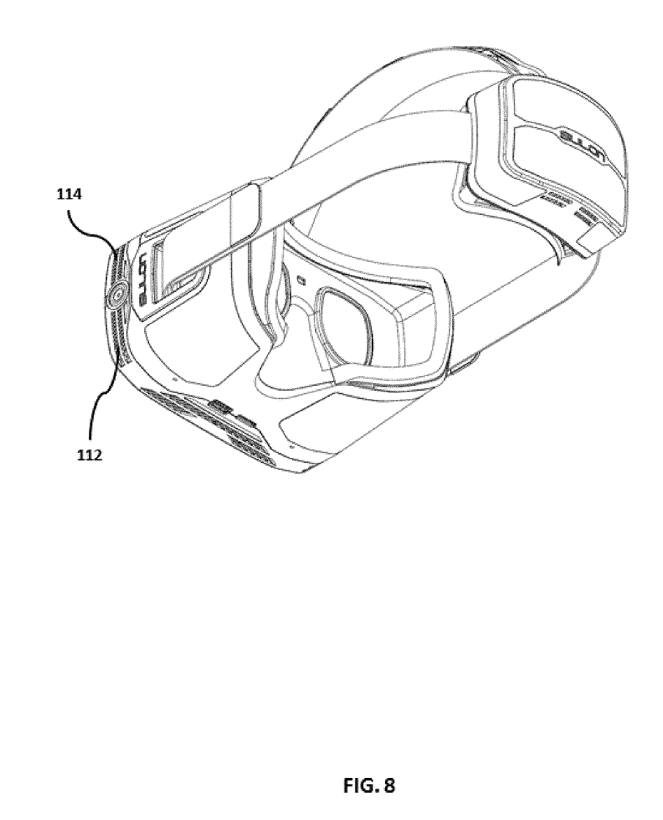

Referring now to FIG. 7 and FIG. 8, various views of the HMD are shown. With reference to the visor housing 102, a plurality of intake vents 112 and exhaust vents 114 are disposed around its periphery to permit airflow into and out of, respectively, the visor housing, aided by the air circulation provided by the radial fans.

In the depicted embodiment, louvres are disposed along the side of the periphery of the visor housing, as shown in FIG. 7. In this case, the exhaust vents 114 are disposed above and proximal the intake vents 112. Since both exhaust vents 114 and intake vents 112 are disposed along each side of the periphery, they are spaced apart by a closed region 113 to inhibit reintroduction of the hot exhaust air from the exhaust vent 114 into the intake air entering the intake vent 112. Further, the louvres of the intake vent and the neighbouring exhaust vent are preferably angled so as not cause convergence of the intake and exhaust air flows. A similar closed region 113 is preferably disposed between the exhaust vent and any intake vents neighbouring the exhaust vent along the top of the periphery. As previously described, further intake vents may be situated along the bottom edge of the periphery, a configuration which may further benefit from the stack effect. The cooling system may further comprise one or more intake fans disposed adjacent one or more inlets to further enhance intake of ambient air into the visor housing; while further fans may increase operating noise during use, higher cooling rates may be achieved.

Although the exhaust vents and intake vents are shown embodied as louvered apertures in the periphery of the visor housing, other embodiments are contemplated. For example, the apertures may be left entirely open, or covered by a grille, a screen or other air-permeable cover. However, the apertures and covers should be selected and sized to permit sufficient airflow for the cooling system across a range of ambient and operating conditions. For example, louvres should not so constrain the effective flow area of the apertures as to overly reduce the achievable airflow induced by the fans, or so as to overly increase the power consumption of the fans to achieve a given airflow.

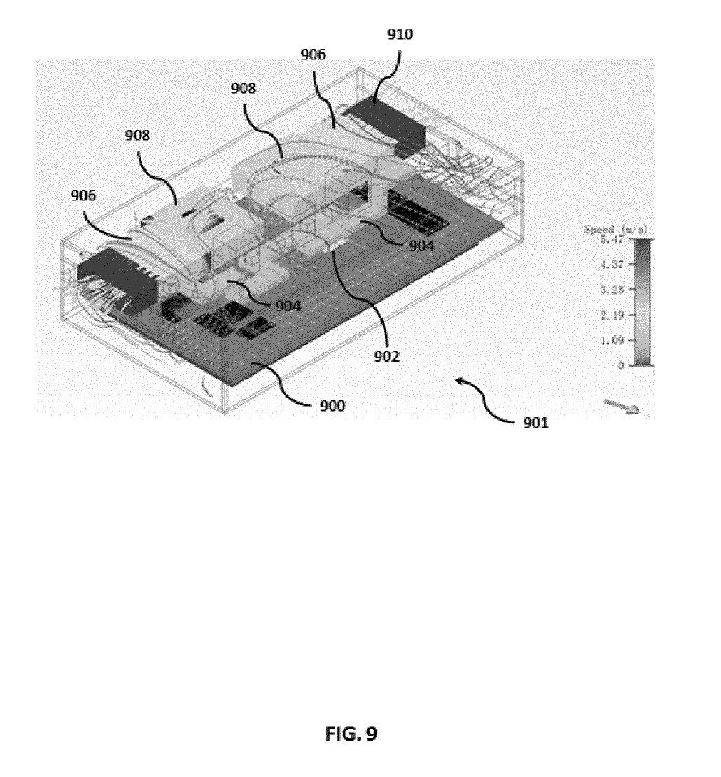

FIG. 9 is an air flow diagram showing an embodiment, such as the first embodiment, of the cooling system 901 in use. The processor 902 on the motherboard 900 is the primary source of heat. Most of the heat from the processor 902 is transferred from the processor 902 to the heat sink, and from the heat sink, along the heat pipes 904 toward each of the sets of fins 906 downstream of the fans 908; some heat from the processor 902 may be transferred by convection or conduction to the air surrounding the processor, by radiation to surrounding colder surfaces or by conduction outwardly from the processor 902 through the motherboard 900. Each heat pipe 904 conducts heat along its length from the heat sink toward the fins 906 that are thermally coupled to the heat pipe 904.

Meanwhile, each fan 908 is driven to induce a negative pressure within the visor housing, which draws colder ambient air from the surrounding environment into the fan inlet. Some or all of the intake air travels across the motherboard 900 on its way towards the fan 908 generally from the intake vents disposed along the lower regions of the visor housing, thereby cooling the motherboard 900 and its components by convection. It will be appreciated that intake air from the intake vents disposed along the top edge of the periphery may travel almost directly to the intake without cooling any components of the motherboard. Each fan emits the air from its respective fan outlet, across the fins 906 thermally coupled to the heat pipe 904, thereby causing convective heat transfer from the fins 906 to the air. The air is then directed by the outlet 910 through the aperture of the exhaust vent.

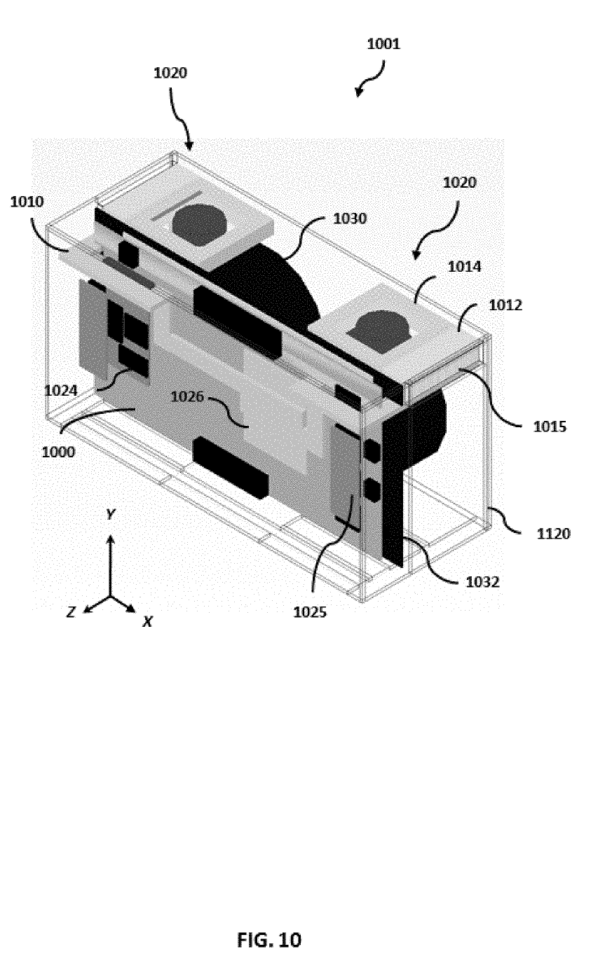

Further embodiments of the cooling system will now be described with reference to FIGS. 10 to 20. These further embodiments illustrate, for example, alternate placements of the fans and vents.

FIGS. 10 to 13 illustrate a second embodiment of the cooling system 1001 and motherboard 1000 for use in an HMD wherein the fans of the cooling system are disposed substantially transversely to the motherboard.

As in previous embodiments, the motherboard 1000 is coupled to various components for use in an HMD, the components including: a processor 1002, a heat sink 1026 abutting the processor 1002, DDR RAM 1025 (optionally, four chips), an SSD 1024, a display 1032 (optionally, a Liquid Crystal Module plate), and a pair of lenses 1030. Further, as above, the cooling system 1001 includes a pair of heat dissipation components 1020 together comprising a pair of heat pipes 1010, fins 1012, and radial fans 1014. Each heat pipe 1010 is thermally coupled to the heat sink 1026 of the processor 1002 at a heat sink end and to the fins 1012 at a heat dissipation end in order to conduct heat from the heat sink 1026 to the fins 1012. The heat pipes 1010 may be jogged around components of the motherboard.

A visor housing 1120 for the motherboard 1000 and cooling system, includes a plurality of intake vents 1102, and at least two exhaust vents 1104. The intake vents 1102 are shown disposed along a bottom portion of the visor housing 1120. The exhaust vents 1104 are disposed along a top portion of the sides of the visor housing 1120, adjacent the fins 1012 for dispelling heated exhaust air from the visor housing 1120 by air flow created by the fans in the direction shown by the arrows e.

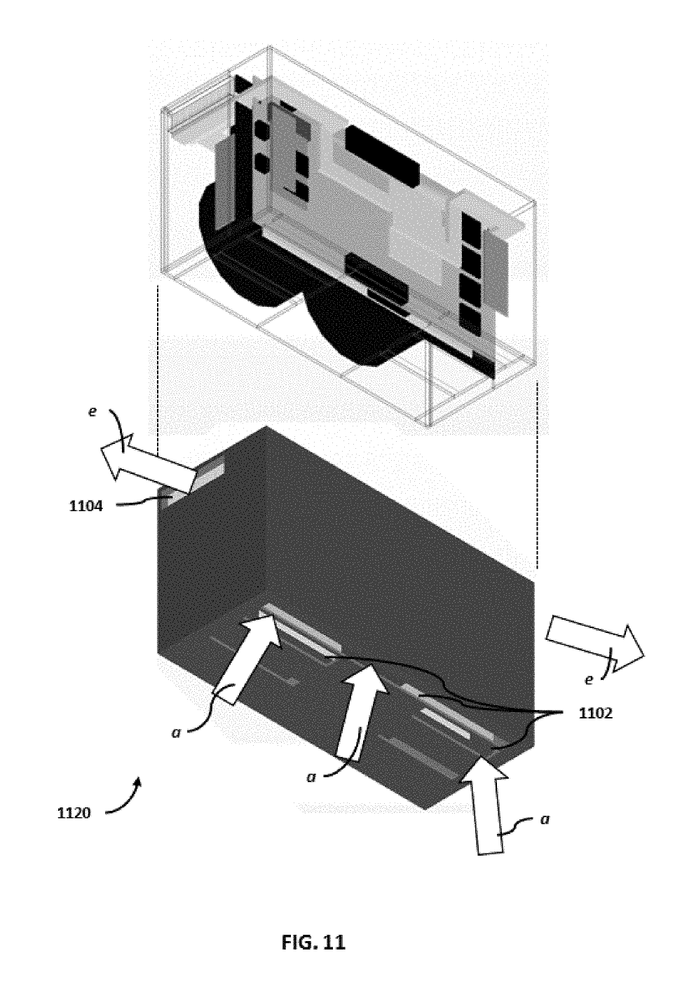

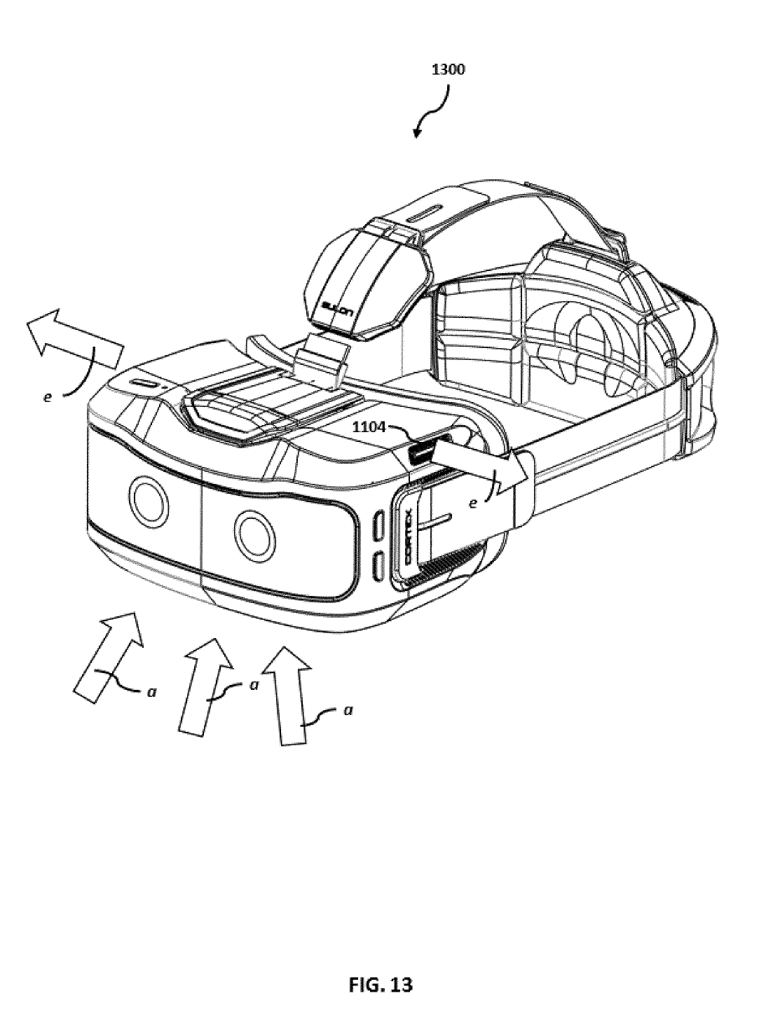

Unlike in the first embodiment, the fans 1014 of the second embodiment are disposed substantially transversely to the motherboard 1000. Accordingly, as shown, the fans 1014 are disposed along the illustrated X-Z plane along the top portion of the visor housing 1120 shown in FIG. 13 (and schematically and transparent in FIG. 10, and schematically in FIG. 11), while the motherboard 1000 is disposed along the illustrated X-Y plane in FIG. 10.

FIG. 11 provides an exploded perspective view of the second embodiment of the cooling system 1001 and motherboard 1000. FIG. 11, illustrates the relationship between the visor housing 1120 and the components it houses, and further illustrates the plurality of intake vents 1102, and the pair of exhaust vents 1104 through the visor housing 1120.

FIG. 13 shows a top perspective view of an exemplary HMD 1300 configured for use with the second embodiment of the cooling system 1001 and motherboard 1000. FIG. 13 illustrates various components of the exemplary HMD 1300. In use, the fans 1014 draw ambient air through the intake vents 1102 in the direction shown by the arrows a, across the components of the motherboard 1000, and then blows the air across the fins 1012 and out through the exhaust vents 1104 in the direction shown by the arrows e. By drawing air that is colder than the components of the motherboard across the motherboard 1000, heat from the components is transferred to the air. Therefore, the air temperature at the inlet of the fan 1014 is higher than the temperature of the ambient air, but preferably colder than the temperature of the heat pipes 1010 and the fins 1012 thermally coupled to the heat pipes 1010 so that heat is transferred from the heat pipes 1010 and/or the fins 1012 to the air.

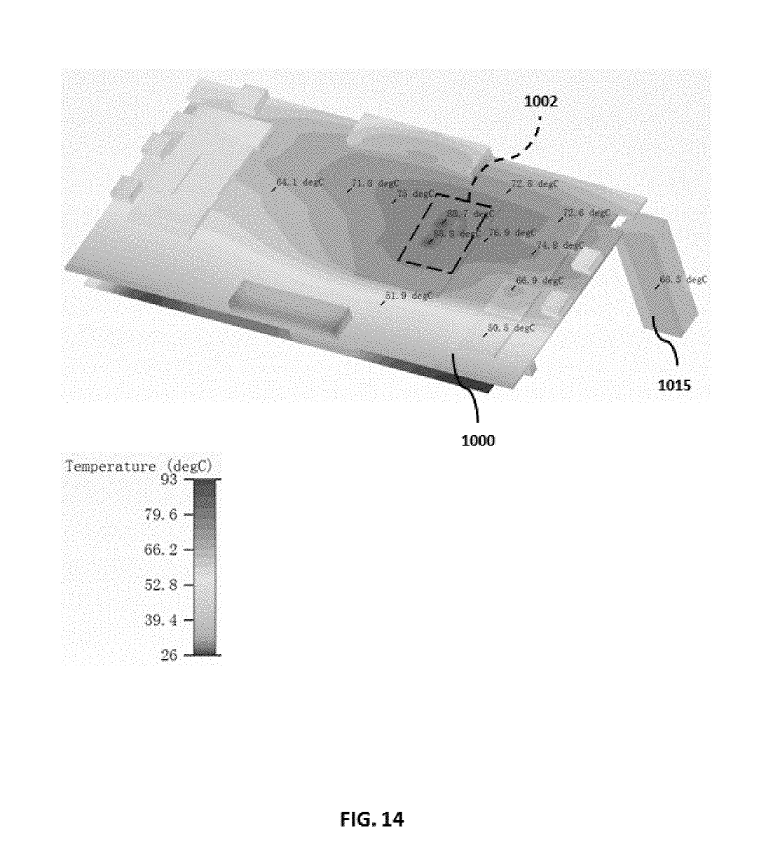

FIG. 14 shows a possible heat map for an exemplary thermal simulation conducted using the second embodiment of the cooling system 1001 and motherboard 1000 with an ambient temperature of 25° C. As shown, at the processor 1002 the temperature may approach and preferably not exceed 90° C.

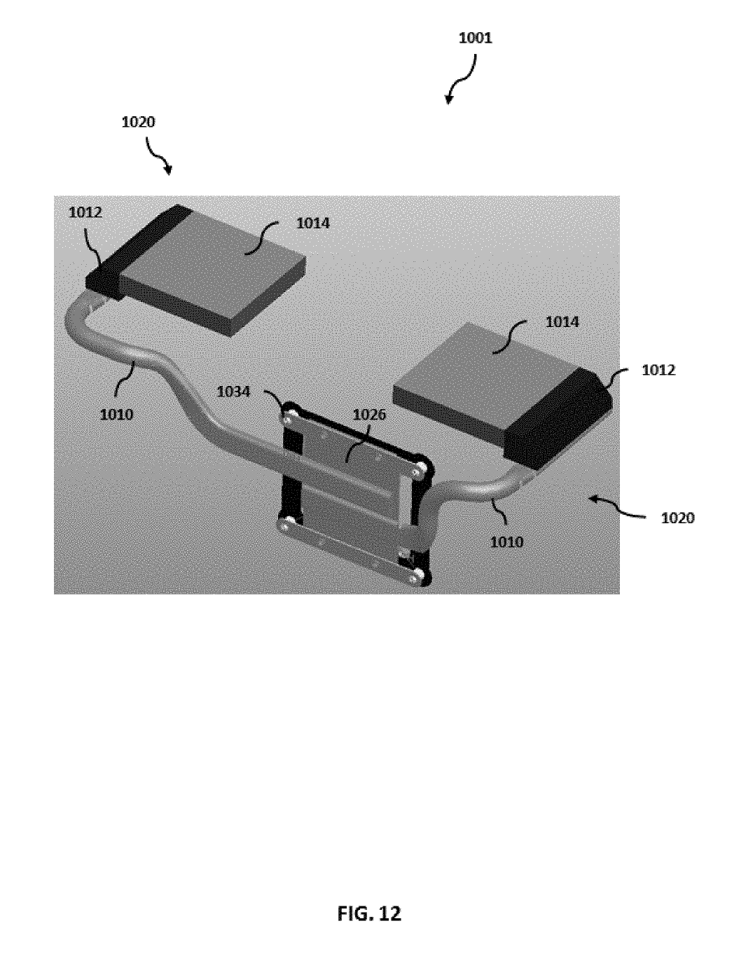

FIG. 12 is an isolated view of the heat pipes 1010, heat sink 1026, fans 1014 and mounting bracket 1034 of the second embodiment of the cooling system 1001 and motherboard 1000. The fans 1014 are shown disposed transversely to the heat sink 1026 and, by extension, the motherboard 1000 shown in FIG. 10.

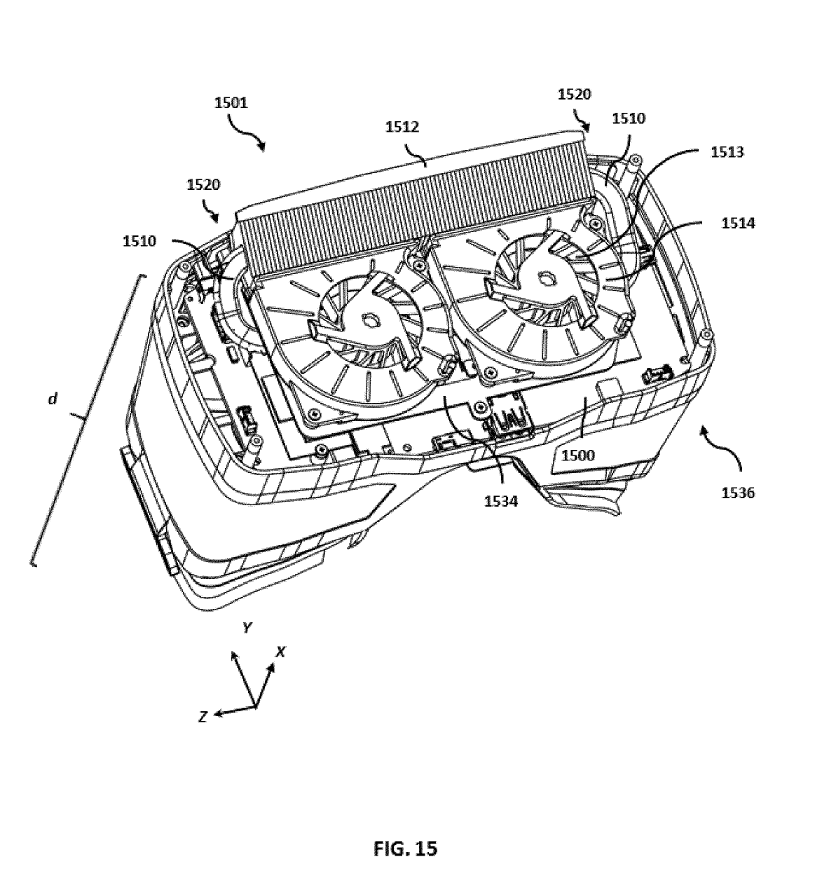

FIG. 15 is a front perspective view of a third embodiment of the cooling system 1501 and motherboard 1500 with fans 1514 mounted substantially parallel to the motherboard 1500 along its outer surface. The cameras and front panel of the visor housing 1536 has been removed for clarity of illustration. The motherboard 1500 is similarly coupled to components for use in an HMD, including a processor and a heat sink abutting the processor (neither is shown). The cooling system 1501 comprises two cooling subsystems 1520, which include at least one heat pipe 1510, fins 1512 and a pair of radial fans 1514. The cooling system 1501 may be mounted to the motherboard 1500 utilizing the illustrated mounting bracket 1534. The heat pipes 1510 are coupled to the heat sink at a heat sink end and to the fins 1512 at a heat dissipation end in order to communicate heat from the heat sink to the fins 1512.

This third embodiment of the cooling system 1501 may increase the depth d of the visor housing 1536 from the user's face relative to other embodiments if, for example, cameras are coupled to the motherboard 1500 for camera-based tracking. The increased depth d may result because both of the cooling subsystems 1520 are substantially conjoined creating an obstruction about the about the vertical (Y-axis) centre of the visor housing 1536 and further because the fans 1513 are displaced lower (i.e., in the −Y direction) toward the region that is equivalent to the region where the cameras 110 are shown in the first embodiment in FIGS. 1 and 2. Any cameras in this embodiment may therefore have to be mounted approximately forward (i.e., further into the X direction than in FIG. 1) of the fans 1514 or shifted downwards away from the vertical centre of the motherboard. However, this configuration may free an area toward either side edge of the visor housing 1536 before the motherboard 1500, and may further permit the use of larger fans 1514, as shown in FIG. 15. Although the fins 1512 are shown as substantially contiguous along the opposed dissipation ends of the heat pipes 1510, they may be separate. In either configuration, the dissipation ends of the heat pipes 1510 may extend along the entire distance of the fins 1512 adjacent both fans 1514, or they may extend only along that distance of the fins 1512 that is adjacent the fan 1514 on the same side of visor housing 1536. Alternatively, a single heat pipe 1510 may extend from the processor, to the fins 1512, and along the entire distance of all the fins 1512 adjacent both fans 1514.

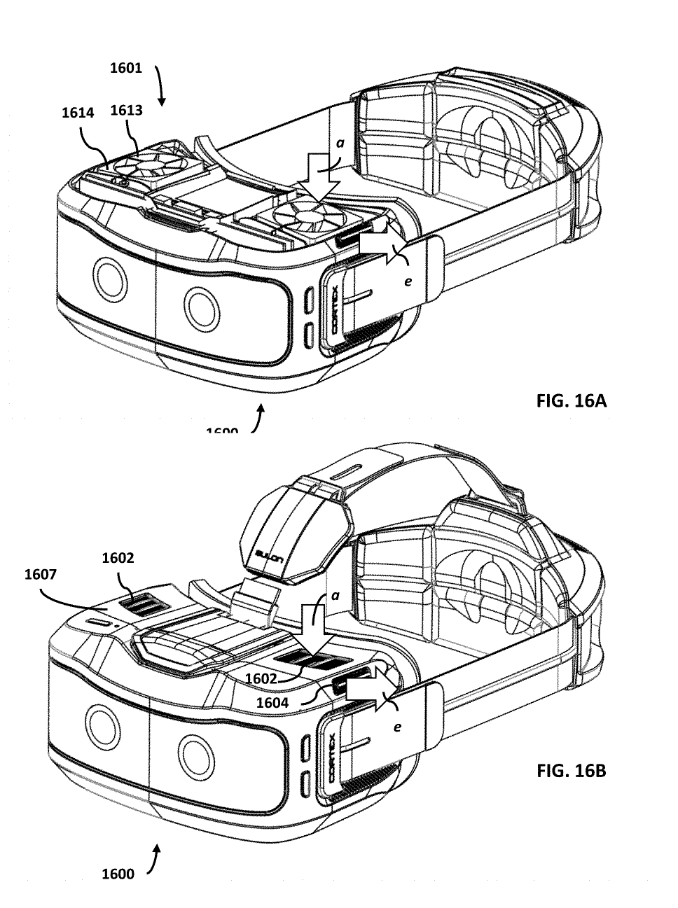

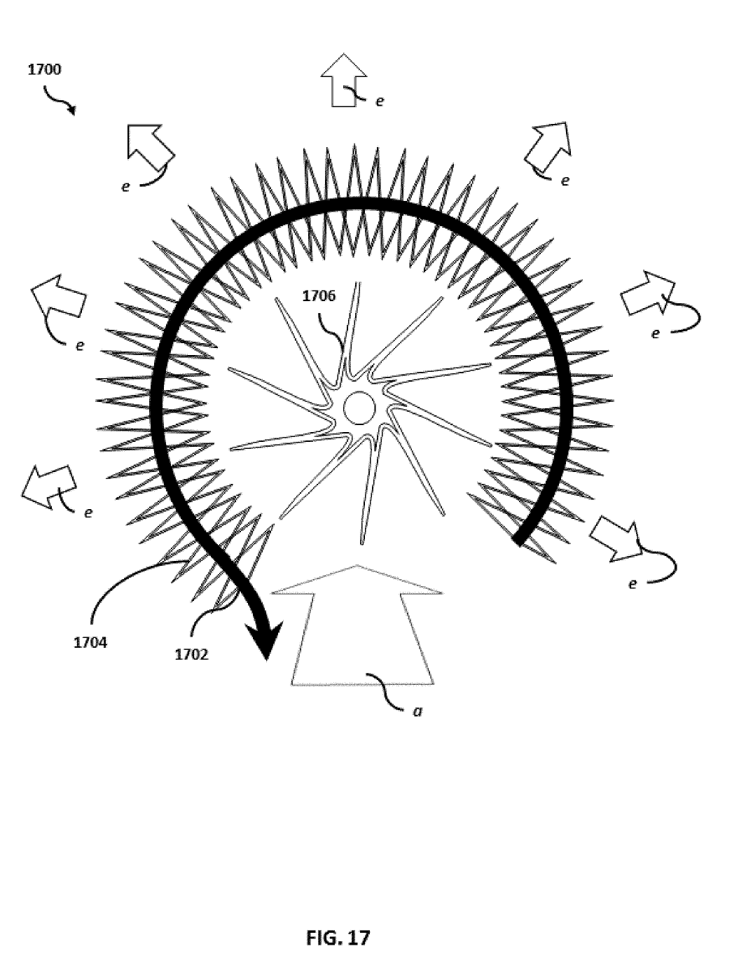

FIGS. 16A and 16B show a front perspective view of a fourth embodiment of the cooling system 1601 wherein the fans 1614 are mounted transversely to the motherboard (not shown), and wherein the fans 1614 are directed through exhaust vents 1604 of the visor housing 1600 (shown in FIG. 17) towards the environment along the direction of the arrows e. As in previous embodiments, the motherboard is mounted within the HMD's visor housing 1600 approximately parallel to the front panel or face of the visor housing 1600, and is coupled to various components (including a processor and heat sink). The visor housing 1600 comprises a top panel 1607, which is shown in place in FIG. 16B and removed in FIG. 16A to reveal the placement of the fans 1614 within the visor housing 1600. The fans 1614 are disposed transversely to the motherboard within the visor housing, with their fan inlets 1613 situated on the uppermost surfaces of the fans 1614 axially aligned with intake vents through the top panel 1607 of the visor housing 1600, and their fan outlets aligned with exhaust vents 1604 through the visor housing 1600. As in other embodiments, the cooling system of the fourth embodiment may include fins (not shown), at least one heat pipe (not shown) and fans 1614. Each heat pipe is thermally coupled to the heat sink of the processor at a heat sink end and to the fins at a heat dissipation end in order to communicate heat from the heat sink to the fins. The fins may form or connect with a guide to guide air from within the visor housing or from each intake vent in the visor housing to the inlet of each fan. Alternatively, the fins may form or connect with an outlet to guide air from the fan to the nearest exhaust vent out of the visor housing.

In this fourth embodiment, the illustrated fans are shown to be radial fans 1614. In use, the radial fans 1614 draw ambient air from the environment above the HMD through the intake vents 1602 of the visor housing 1600, and further through the fan inlets 1614. The fans 1614 then expel the air across the fins and the heat pipes, through the exhaust vents 1604 into the environment along the direction of the arrows e. The intake vents 1102 may be louvered apertures. Alternatively, the fans may be axial fans which draw ambient air from environment through intake vents along the bottom of the visor housing and exhaust the air upwards through exhaust vents on the top of the visor housing, with the fins being stationed either before or after the fans. In the that case, the vents shown in FIG. 16B as exhaust vents 1604 may be omitted, and the vents shown as intake vents 1602 would be exhaust vents instead.

FIG. 17 illustrates a possible embodiment of the cooling system 1700 incorporating a rounded heat pipe 1702 having a plurality of transverse heat fins 1704 disposed around a radial fan 1706. A guide (not shown) having an outlet may at least partially enclose the illustrated cooling system to direct air out of the visor housing through an exhaust vent in the visor housing. In use, the fans 1706 would thus direct air over the fins 1704 and through the outlet out of the visor housing in order to dispel heat from the visor housing and the processor therein. It will be appreciated that the other embodiments of the cooling system described herein may be modified to incorporate aspects of the configuration of the embodiment of FIG. 17. It will be appreciated further that the cooling system 1700 provides a greater length of the heat pipe 1702 surrounding the fan 1706 than might otherwise be possible with a substantially straight length of fins as in the other embodiments described herein. In operation, the fan 1706 draws air along the direction shown by the arrow a (i.e., along the fan's axis of rotation) and directs the air radially outwards across the fins 1704 and heat pipe 1702 along the directions shown by the arrows e toward adjacent exhaust vents in the visor housing (not shown).

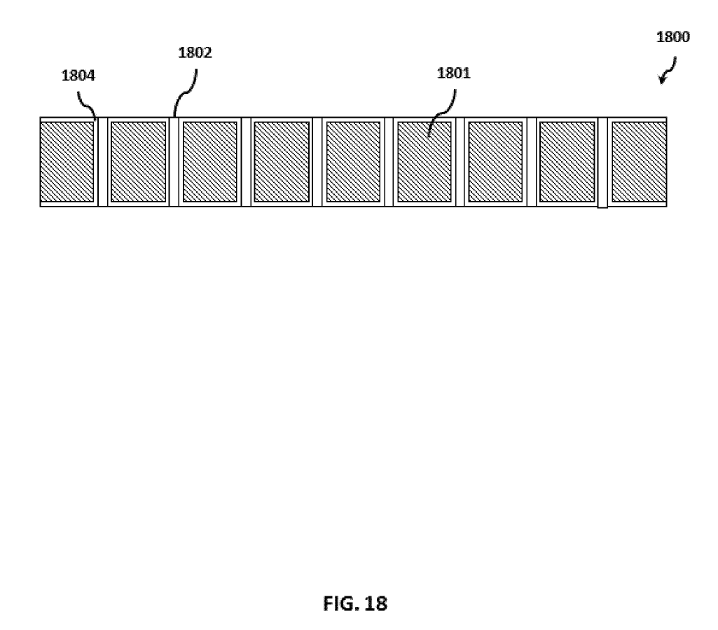

As described above, in addition to the exhaust vents, various surfaces of the HMD's visor housing may be perforated for enhancing airflow. Further. the perforations may be lined with thermally conductive materials that enhance heat transfer, such as aluminum, copper, or other suitable metallic of non-metallic material. FIG. 18 illustrates a possible embodiment of a panel 18 of the visor housing having a solid portion core 1801 and perforations 1802 disposed therethrough. Preferably, a conductive medium 1804 is disposed on opposing surfaces of the panel and through the perforations, thus forming “thermal vias”. If the thermally conductive medium 1804 is metallic, the entire panel may thus be metal-coated or metallized, even though the solid core 1801 is of a non-metallic material. It will be appreciated that thermal vias can achieve a similar heat conducting effect as fins.

FIGS. 19A to 19C illustrate various configurations of the cooling system's fans and motherboard for an HMD. As shown in FIGS. 19A and 19B, the fans 1914 may be disposed along the side or top of the visor housing, such that the fans 1914 are approximately transverse to the surface of the motherboard and thus the processor 1902. Alternatively, as shown in FIG. 19C, the fans 1914 may be adjacent the surface of the motherboard, and thus the processor 1902, i.e. approximately parallel the surface of the motherboard. The first embodiment and third embodiment of the cooling system and motherboard described above with respect to FIGS. 2 to 9 and 15, respectively, generally relate to the configuration illustrated in FIG. 19C. The second and fourth embodiment of the cooling system and motherboard described above in relation to FIGS. 10 to 14, 16A and 16B, respectively, generally relate to FIG. 19B. Air travel into the fans 1914 is denoted by the arrows a and air travel from the fans 1914 across the heat pipes 1910 is denoted by the arrows e. It will be appreciated that other configurations are contemplated.

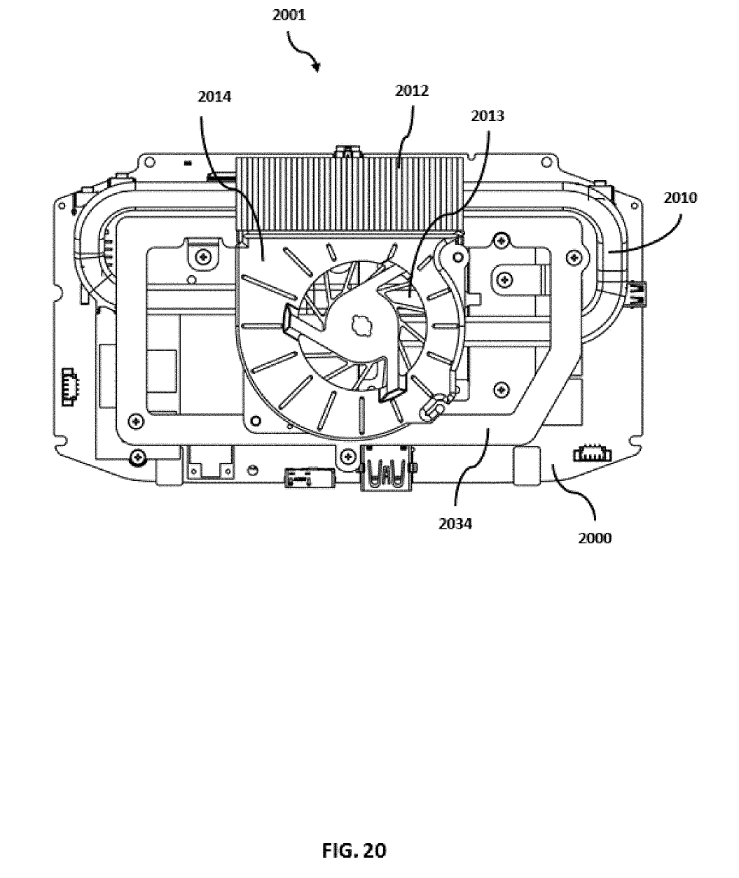

FIG. 20 shows a further embodiment of the cooling system 2001 wherein the cooling system comprises one fan 2014 instead of the two fans shown in other embodiments. The single fan 2014 is disposed near the centre of the motherboard 2000, thereby maintaining relatively even weight distribution across the motherboard 2000. The cooling system 2001 of this embodiment provides a substantially obstruction free region on either side of the fan 2014. During operation, the fan 2014 draws air through its fan inlet 2013. The air may enter through the face of the fan 2014 facing the motherboard 2000 or through the opposite face. In this embodiment, the visor housing (not shown) may have an intake vent on a front panel opposite the fan inlet 2013. Alternatively, the visor housing may have various intake vents around its periphery, as in previous embodiments, so that air is drawn through those intake vents across the components of the motherboard 2000, prior to being forced by the fan 2014 across the fins 2012 and heat pipe 2010, out an exhaust vent in the visor housing and into the surrounding environment. In a still further embodiment, the cooing system may omit the cooling pipe and fins so that one or more fans disposed within the visor housing draws air through the visor housing across the motherboard to cool the components mounted thereon.

In one embodiment, an HMD for AR applications comprises at least one cooling subsystem that comprises a fan.

In another embodiment, an HMD for AR applications comprises: a visor housing having two or more exhaust vents and one or more intake vents; a motherboard disposed within the visor housing; at least one processor mounted to the motherboard; at least one camera mounted to the visor housing; and at least a pair of cooling subsystems disposed within the visor housing to dissipate heat generated by the at least one processor from the exhaust vents and receive air flow from the intake vents. The cooling subsystems are arranged to provide generally balanced horizontal weight to the visor housing.

In yet another embodiment, a cooling system for an AR HMD is disposed predominantly on an opposing side of a display of an HMD from a user so as to not obstruct viewing of the display by the user. The HMD comprises a visor housing having a display viewable by a user wearing the HMD and electronics for driving the display. The cooling system comprises a plurality of fans directing airflow outward from the HMD to an environment surrounding the HMD, and at least two of the plurality of fans are disposed along opposing sides of a vertical midpoint of the HMD.

The HMD may further comprise at least one camera facing outward from an outer surface of the visor housing opposed to a wearing surface of the visor housing abutting the user, and the cooling system may be disposed between the outer surface and the display.

The cooling system may further comprise one or more heat pipes thermally coupled at a first end to one or more heat generating elements of the HMD and at a second end to a dissipation area within airflow generated by one of the plurality of fans. The cooling system may further comprise one or more sets of heat fins disposed at each dissipation area and thermally coupled to the second end of the respective heat pipe.

The respective fan may be disposed between the dissipation area and an exhaust vent of the HMD and the fan may draw exhaust air over the dissipation area and outward through the exhaust vent. Alternatively, the dissipation area may be disposed between the respective fans and an exhaust vent of the HMD and the fan blows exhaust air over the dissipation area and outward through the exhaust vent.

The cooling system may further comprise a set of exhaust vents disposed along peripheral surfaces of the HMD along an exhaust airflow of each fan. The peripheral surface may include an upper surface of the HMD and may further include two opposing side surfaces of the HMD. The cooling system may further comprise a set of intake vents disposed along the peripheral surface generally opposed to the exhaust vents to cause an airflow within the visor housing such that ambient air is drawn into the visor housing as a result of the cooling system dissipating exhaust air from the exhaust vents.

At least one of the plurality of the fans may be disposed along an upper portion of the visor housing and directing heated air vertically upward from the HMD.

In at least one embodiment, at least two of the plurality of fans are disposed along an upper portion of the visor housing and direct heated air vertically upward from the HMD. The at least two of the plurality of fans may be adjacent one another and generally disposed symmetrically about the vertical midpoint of the HMD.

In at least one other embodiment, at least two of the plurality of fans are disposed along opposing side surfaces of the HMD and direct heated air horizontally outward from the HMD.

The plurality of fans may comprise axial fans or radial fans.

In a further embodiment, an AR HMD comprises: a visor housing having a display viewable by a user wearing the HMD electronics for driving the display, and a cooling system disposed predominantly on an opposing side of the display from the user so as to not obstruct viewing of the display by the user. The cooling system comprises a plurality of fans directing airflow outward from the HMD to an environment surrounding the HMD. At least two of the plurality of fans are disposed along opposing sides of a vertical midpoint of the HMD.

In a still further embodiment, a cooling system for an AR HMD comprises a visor housing having a display viewable by a user wearing the HMD and electronics for driving the display. The cooling system is disposed predominantly on an opposing side of the display from the user so as to not obstruct viewing of the display by the user, and the cooling system comprises at least one fan directing airflow upward from the HMD.

Although the foregoing has been described with reference to certain specific embodiments, various modifications thereto will be apparent to those skilled in the art without departing from the spirit and scope of the invention as outlined in the appended claims.

We claim:

1. A cooling system for an augmented or virtual reality (AR/VR) head mounted device (HMD), the HMD comprising a visor housing having a display viewable by a user wearing the HMD and electronics for driving the display, the cooling system being disposed predominantly on an opposing side of the display from the user so as to not obstruct viewing of the display by the user, the cooling system comprising: a plurality of fans directing airflow outward from the HMD to an environment surrounding the HMD, at least two of the plurality of fans being disposed along opposing sides of a vertical midpoint of the HMD.

2. The cooling system of claim 1, wherein the HMD further comprises at least one camera facing outward from an outer surface of the visor housing opposed to a wearing surface of the visor housing abutting the user, and wherein the cooling system is disposed between the outer surface and the display.

3. The cooling system of claim 1, further comprising one or more heat pipes thermally coupled at a first end to one or more heat generating elements of the HMD and at a second end to a dissipation area within airflow generated by one of the plurality of fans.

4. The cooling system of claim 3, further comprising one or more sets of heat fins disposed at each dissipation area and thermally coupled to the second end of the respective heat pipe.

5. The cooling system of claim 3, wherein the dissipation area is disposed between the respective fans and an exhaust vent of the HMD and the fan blows exhaust air over the dissipation area and outward through the exhaust vent.

6. The cooling system of claim 3, wherein the respective fan is disposed between the dissipation area and an exhaust vent of the HMD and the fan draws exhaust air over the dissipation area and outward through the exhaust vent.

7. The cooling system of claim 1, further comprising a set of exhaust vents disposed along peripheral surfaces of the HMD along an exhaust airflow of each fan.

8. The cooling system of claim 7, wherein the peripheral surface includes an upper surface of the HMD.

9. The cooling system of claim 7, wherein the peripheral surface includes two opposing side surfaces of the HMD.

10. The cooling system of claim 7, further comprising a set of intake vents disposed along the peripheral surface generally opposed to the exhaust vents to cause an airflow within the visor housing such that ambient air is drawn into the visor housing as a result of the cooling system dissipating exhaust air from the exhaust vents.

11. The cooling system of claim 1, wherein at least one of the plurality of fans is disposed along an upper portion of the visor housing and directs heated air vertically upward from the HMD.

12. The cooling system of claim 12, wherein at least two of the plurality of fans are disposed along an upper portion of the visor housing and direct heated air vertically upward from the HMD.

13. The cooling system of claim 13, wherein the at least two of the plurality of fans are adjacent one another and generally disposed symmetrically about the vertical midpoint of the HMD.

14. The cooling system of claim 1, wherein at least two of the plurality of fans are disposed along opposing side surfaces of the HMD and direct heated air horizontally outward from the HMD.

15. The cooling system of claim 1, wherein the plurality of fans comprise axial fans.

16. The cooling system of claim 1, wherein the plurality of fans comprise radial fans.

17. An augmented or virtual reality (AR/VR) head mounted device (HMD), the HMD comprising a visor housing having a display viewable by a user wearing the HMD electronics for driving the display, and a cooling system disposed predominantly on an opposing side of the display from the user so as to not obstruct viewing of the display by the user, the cooling system comprising: a plurality of fans directing airflow outward from the HMD to an environment surrounding the HMD, at least two of the plurality of fans being disposed along opposing sides of a vertical midpoint of the HMD.

18. A cooling system for an augmented or virtual reality (AR/VR) head mounted device (HMD), the HMD comprising a visor housing having a display viewable by a user wearing the HMD and electronics for driving the display, the cooling system being disposed predominantly on an opposing side of the display from the user so as to not obstruct viewing of the display by the user, the cooling system comprising at least one fan directing airflow upward from the HMD.
